(19) United States
(12) Patent Application Publication
(10) Pub. No.: US 2025/0311337 A1
(43) Pub. Date: Oct. 2, 2025

(54) DOPANT ENGINEERING TO SUPPRESS EPITAXIAL MISSHAPENNESS IN N-TYPE EPITAXIAL SOURCE-DRAIN TRANSISTORS

(71) Applicant: Intel Corporation, Santa Clara, CA (US)

(72) Inventors: Shishir Pandya, Hillsboro, OR (US); Kiran Chikkadi, Hillsboro, OR (US); Anushka Bansal, Portland, OR (US); Robert Ehlert, Portland, OR (US); Rohan Bambery, Portland, OR (US); Anant Jahagirdar, Portland, OR (US); Sandrine Charue-Bakker, Portland, OR (US); Anand Murthy, Portland, OR (US)

(73) Assignee: Intel Corporation, Santa Clara, CA (US)

(21) Appl. No.: 18/621,656

(22) Filed: Mar. 29, 2024

(51) Int. Cl. H01L 29/08; H01L 29/06; H01L 29/167; H01L 29/423; H01L 29/66; H01L 29/775; H01L 29/786

(52) U.S. Cl. CPC H10D 62/151; H10D 30/014; H10D 30/031; H10D 30/43; H10D 30/6757; H10D 30/6735; H10D 62/116; H10D 62/834

(57) ABSTRACT

Methods, transistors, and systems are discussed related to forming epitaxial n-type source and drain materials on one or more semiconductor structures. The n-type source and drain materials include an n-type dopant in a bulk material. A first region of each of the n-type source and drain materials laterally adjacent to the one or more semiconductor structures has a lower n-type dopant concentration than a second region over the first region. The second region is formed by implanting the n-type dopant and subsequent anneal.

### BACKGROUND

Transistor cell density is an important characteristic in integrated circuits as increased cell density improves device capability. Striving to keep Moore's Law alive, efforts are being made to double transistor density every two years. This means that in both logic and memory library cells, transistor semiconductor (e.g., fin) pitches have become tighter and the raised epitaxial source/drain (e.g., “epi” source/drain) on neighboring fins are closer to each other than ever before. This poses a risk of shorting between two neighboring epi sources/drains if their size is too large. Therefore, a yield cliff is established to limit the maximum epi source/drain size to prevent epi-to-epi shorts.

One approach to staying below the yield cliff is to reduce the size of the epi source/drain. However, this approach comes at the cost of device performance since the smaller epi source/drain results in a smaller contact surface area and in turn an increase in the contact resistance.

It is desirable to increase transistor cell density while providing high quality and relatively large epi sources/drains for improved device performance. It is with respect to these and other considerations that the present improvements have been needed. Such improvements may become critical to increase cell density in higher performance integrated circuit electronic devices.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 provides illustrative views of an exemplary transistor structure having epitaxial source and drain structures with reduced misshapenness;

FIG. 2 illustrates a flow diagram illustrating an example process for fabricating transistor structures having epitaxial source and drain structures with reduced misshapenness;

FIGS. 3, 4, 5, 6, 7, 8, 9, and 10 illustrate cross-sectional side views of example transistor structures as particular fabrication operations are performed to generate sources and drains with reduced misshapenness and improved electrical characteristics;

FIG. 11 is an illustrative diagram of a mobile computing platform employing a device having a reduced misshapenness implanted epitaxial (Epi) source and/or drain (S/D) transistor; and

FIG. 12 is a functional block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Transistor structures, device structures, apparatuses, integrated circuits, computing platforms, and methods are described herein related to transistors having reduced n-type epitaxial sources and drains with reduced misshapenness for increased cell density while maintaining large sources and drains for reduced contact resistance. Such n-type epitaxial sources and drains have a low n-type dopant concentration region grown to reduce misshapenness of the epitaxial material and a high n-type dopant concentration implant region over the low n-type dopant concentration region.

As discussed, it is desirable to increase transistor cell density while maintaining high quality transistors inclusive of high quality, relatively large epitaxial sources and drains. In particular, it is desirable to have relatively large epitaxial sources and drains to reduce contact resistance to the transistor device. When increasing cell density, there are challenges in maintaining relatively large epitaxial sources and drains as shorts can occur between adjacent sources and drains. These shorts can be caused by epi source and drain misshapenness. For example, when forming many epitaxial sources and drains, there is a deviation around the target lateral size of the epi sources and drains (e.g., a lateral x- or y-dimension in plane with the wafer work surface while looking down at the work surface). Misshapenness of epitaxial sources and drains increases this deviation (as measured by standard deviation, for example), which is evident across a wafer, across a die, and even locally within small areas of a single die. Furthermore, the misshapenness of a pair of neighboring epi sources or drains can cause a short if, for example, the misshapenness of each extends toward its neighbor. Therefore, there is a desire to decrease misshapenness of each instance of an epi source and drain to eliminate shorts and increase device reliability.

To continue to increase transistor cell density, minimizing epi source and drain size variation and the misshapenness of each epi source and drain therefore becomes critical to achieve maximum performance of the resultant electronic device. Both p-type and n-type epi are susceptible to this misshapenness, however, the chemistry and the growth kinetics of the n-type epi make the problem particularly acute in growing n-type epi sources and drains. The techniques discussed herein provide a process flow and resultant device structures that utilize particular growth chemistry and growth kinetics of n-type epi to reduce random variation and misshapenness of the n-type epi sources and drains in transistor structures. Such techniques may be deployed in any suitable device architecture such as FinFETs (fin field-effect transistors), GAA-FETS (gate-all-around field-effect transistors), or others.

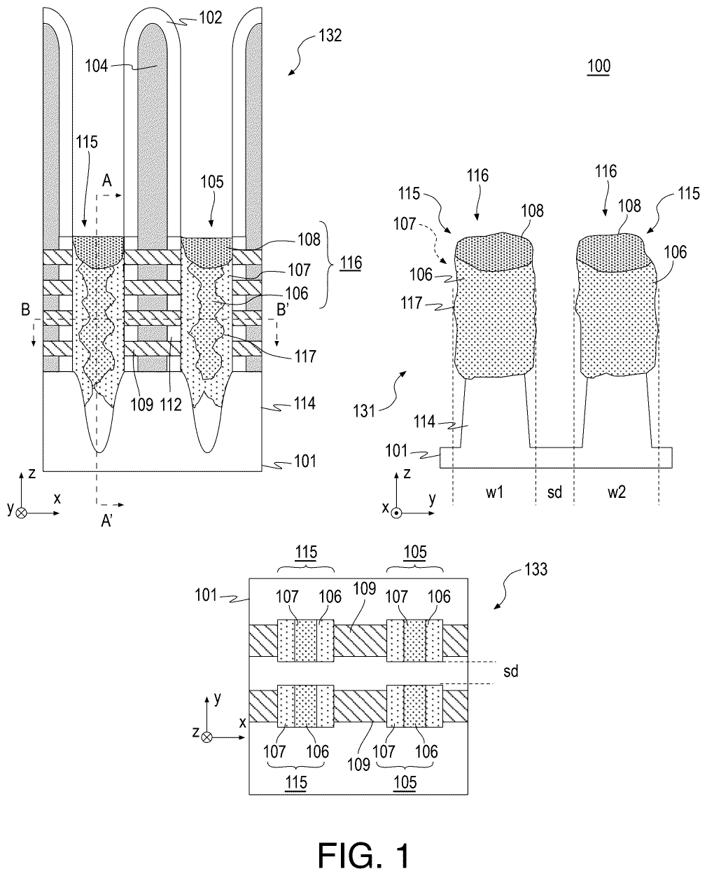

FIG. 1 provides illustrative views of an exemplary transistor structure 100 having epitaxial source and drain structures with reduced misshapenness, arranged in accordance with at least some implementations of the present disclosure. In FIG. 1, a first cross-sectional side view 131 of transistor structure 100 (illustrated in the top-right of FIG. 1) is taken along a fin cut such that a low n-type dopant growth region 106 and a high n-type dopant implant region 108 of a source 115 and a drain 105, which are over substrate 101, are visible. It is noted that both source and drain 105 may have the same or similar low n-type dopant growth region 106 and high n-type dopant implant region 108. For example, each of source 115 and drain 105 include an epitaxial structure 116 including low n-type dopant growth region 106, high n-type dopant implant region 108, and, optionally, n-type doped epitaxial nucleation layer 107.

A second cross-sectional side view 132 of transistor structure 100 (illustrated in the top-left of FIG. 1) is taken along a gate cut such that semiconductor structures 109, source 115, and drain 105 are visible, along with other components of transistor structure 100 as discussed below. For example, first cross-sectional side view 131 provides a view at the A-A′ cut through second cross sectional side view 132. Furthermore, any number of fin structures (e.g., inclusive of a dummy gate 104, isolation materials 102, 112, semiconductor structures 109, sacrificial layers 108, and so on) may be provided along the x-axis with shared sources 115 and/or drains 105. Isolation material 112 may also be characterized as a dielectric spacer, spacer, or spacer material as discussed further herein below.

FIG. 1 also shows a cross-sectional top-down view 133 of transistor structure 100 (illustrated in the bottom of FIG. 1) that is taken along a lateral cut to illustrate a layout of transistor structure 100. For example, cross-sectional top-down view 133 provides a view at the B-B′ cut through second cross sectional view 132 with some structures removed for the sake of clarity of presentation. As shown in cross-sectional side view 132 and cross-sectional top-down view 133, neighboring sources 115 and/or neighboring drains 105 may be separated by a separation distance sd. As shown in cross-sectional side view 132 each of sources 115 and drains 105 have a width such as w1, w2, . . . that measures the lateral width of each of sources 115 and drains 105. For example, the lateral widths of sources 115 and drains 105 may be expressed as a wing-span that is half of the difference between the width of sources 115 and drains 105 and the width of semiconductor structures 109 (e.g., a fin width taken in the y-dimension). For example the wing-span (WS) may be half of the difference between the epi width (w1 or w2) and the fin width (FW) such that WS=(w1−FW)/2. In some embodiments, the wing span may be in the range of about 10 to 15 nm for a fin width of about 5 to 15 nm, giving widths of sources 115 and drains 105 (w1, w2, . . . ) in the range of about 25 to 45 nm. However, any suitable source 115 and drain 105 widths may be used.

Notably, with large misshapenness of sources 115 and drains 105, there are difficulties due to deviation from the target widths. First, smaller or deformed sources 115 and drains 105 can reduce contact area to the top of sources 115 and drains 105, the material volume of sources 115 and drains 105, and cause other resistance and contact problems. Furthermore, larger and laterally deformed sources 115 and drains 105 can cause shorts, as discussed above, when the separation distance sd goes to zero. Therefore, it is desirable to reliably form well-shaped sources 115 and drains 105 to reduce the risk of shorts, provide greater device reliability, and, importantly, to allow a relatively large process target for sources 115 and drains 105 widths w1, w2, . . . for increased device performance.

As shown, transistor structure 100 includes substrate 101, fin portions 104, isolation materials 102, 112, semiconductor structures 109, and a dummy gate 104. Sources 115 and drains 105 each include low n-type dopant growth region 106 and high n-type dopant implant region 108, as well as an optional n-type doped epitaxial nucleation layer 107. In some embodiments, n-type doped epitaxial nucleation layer 107 is not deployed. However, in some embodiments, n-type doped epitaxial nucleation layer 107 has a lower n-type dopant concentration relative to low n-type dopant growth region 106, and is used as a seed or nucleation layer for lattice matching to semiconductor structures 109, for example. In some embodiments, high n-type dopant implant region 108 is formed by implant into only low n-type dopant growth region 106. In other embodiments, high n-type dopant implant region 108 is formed by implant into low n-type dopant growth region 106 and n-type doped epitaxial nucleation layer 107. In any event, high n-type dopant implant region 108 is over low n-type dopant growth region 106 and optional n-type doped epitaxial nucleation layer 107 and extends across top surfaces of source 115 and drain 105.

Semiconductor structures 109 extend between source 115 and drain 105. Furthermore, additional lateral instances of semiconductor structures 109 extend between source 115 and another instance of drain 105 (e.g., in the negative x-dimension), and between drain 105 and another instance of source 115 (e.g., in the positive x-dimension) such that the portion of transistor structure 100 illustrated in FIG. 1 may be part of a repeating pattern as part of a transistor cell layout, as is known in the art. Source 115 and drain 105 are epitaxial to semiconductor structures 109, and each of source 115 and drain 105 include an epitaxial structure having a first material doped with an n-type dopant. In some embodiments, the first material is silicon and the n-type dopant is phosphorus such that each of source 115 and drain 105 are phosphorus doped silicon. Although discussed herein with respect to phosphorus, another n-type dopant such as arsenic may be used, with the same dopant concentration characteristics. For example, each of n-type doped epitaxial nucleation layer 107, low n-type dopant growth region 106, and high n-type dopant implant region 108 may be phosphorus doped silicon, with differing dopant concentrations.

Although illustrated with respect to gate-all-around or nano-ribbon semiconductor structures 109, semiconductor structures 109 may be any suitable structure or structures such as a fin of semiconductor material. In the context of FIG. 1, dummy gate 104 is on and between semiconductor structures 109, but dummy gate 104 will later be replaced with a gate structure including a gate electrode and gate dielectric, for example. As discussed further herein below, source 115 and drain 105 include different regions of the first material doped with n-type dopant such that a concentration of the n-type dopant varies in source 115 and drain 105. In some embodiments, the epitaxial structure of source 115 and drain 105 includes a first region (low n-type dopant growth region 106) lateral to one or more of semiconductor structures 109 and a second region (high n-type dopant implant region 108) over the first region and absent from any sidewall 117 of the first region. The first region has a first n-type dopant concentration of not more than 70 percent of a second n-type dopant concentration of the second region. For example, low n-type dopant growth region 106 may be grown using chemistry and growth conditions that offer low misshapenness of growth body of low n-type dopant growth region 106. To reduce contact resistance, high n-type dopant implant region 108 is then formed in a portion of the growth body using implant and anneal techniques such that low n-type dopant growth region 106 has a lower n-type dopant concentration than high n-type dopant implant region 108.

The increase in dopant concentration may be any suitable amount or ratio. As discussed, in some embodiments, low n-type dopant growth region 106 has a first n-type dopant concentration of not more than 70 percent of a second n-type dopant concentration of high n-type dopant implant region 108. In some embodiments, low n-type dopant growth region 106 has a first n-type dopant concentration of not more than 50 percent of a second n-type dopant concentration of high n-type dopant implant region 108. In some embodiments, low n-type dopant growth region 106 has a first n-type dopant concentration of not more than 30 percent of a second n-type dopant concentration of high n-type dopant implant region 108.

In some embodiments, high n-type dopant implant region 108 has an n-type dopant concentration in the range of 3.5 to 4.5×10²¹ cm⁻³. In some embodiments, high n-type dopant implant region 108 has an n-type dopant concentration of not less than 3.5×10²¹ cm⁻³. In some embodiments, high n-type dopant implant region 108 has an n-type dopant concentration of not less than 4.0×10²¹ cm⁻³. In some embodiments, low n-type dopant growth region 106 has an n-type dopant concentration in the range of 1.0 to 2.5×10²¹ cm⁻³. In some embodiments, low n-type dopant growth region 106 has an n-type dopant concentration of not more than 2.5×10²¹ cm⁻³. In some embodiments, low n-type dopant growth region 106 has an n-type dopant concentration of not more than 2.0×10²¹ cm⁻³. In some embodiments, low n-type dopant growth region 106 has an n-type dopant concentration of not more than 1.5×10²¹ cm⁻³.

In some embodiments, high n-type dopant implant region 108 has an n-type dopant concentration of about 4.5×10²¹ cm⁻³, and low n-type dopant growth region 106 has an n-type dopant concentration of about 1.5×10²¹ cm⁻³. In some embodiments, high n-type dopant implant region 108 has an n-type dopant concentration of about 4.5×10²¹ cm⁻³, and low n-type dopant growth region 106 has an n-type dopant concentration of about 2.35×10²¹ cm⁻³. In some embodiments, high n-type dopant implant region 108 has an n-type dopant concentration of about 4.5×10²¹ cm⁻³, and low n-type dopant growth region 106 has an n-type dopant concentration of about 3.0×10²¹ cm⁻³.

In some embodiments, high n-type dopant implant region 108 has an n-type dopant concentration of not less than 3.0×10²¹ cm⁻³, and low n-type dopant growth region 106 has an n-type dopant concentration of not more than 2.5×10²¹ cm⁻³. In some embodiments, high n-type dopant implant region 108 has an n-type dopant concentration of not less than 3.5×10²¹ cm⁻³, and low n-type dopant growth region 106 has an n-type dopant concentration of not more than 1.1×10²¹ cm⁻³. In some embodiments, high n-type dopant implant region 108 has an n-type dopant concentration of not less than 3.5×10²¹ cm⁻³, and low n-type dopant growth region 106 has an n-type dopant concentration of not more than 1.75×10²¹ cm⁻³. In some embodiments, high n-type dopant implant region 108 has an n-type dopant concentration of not less than 3.5×1021 cm⁻³, and low n-type dopant growth region 106 has an n-type dopant concentration of not more than 2.5×10²¹ cm⁻³. Other dopant concentrations may be used.

As shown, low n-type dopant growth region 106 extends across an entirety of a width of the epitaxial structure (e.g., in the y-dimension) and high n-type dopant implant region 108 is at a top of source 115 or drain 105. Notably, high n-type dopant implant region 108 will be at an eventual interface with a source or drain contact and may in contact with a silicide of the source or drain contact. In some embodiments, low n-type dopant growth region 106 is not less than 5 nm from the top surface/interface, and no portion of low n-type dopant growth region 106 extends below the top surface/interface. In some embodiments, low n-type dopant growth region 106 is between about 5 to 10 nm from the top surface/interface. Other details of source 115 and drain 105 and their constituent structures are discussed herein below.

Substrate 101 may include any suitable material or materials and, in some embodiments, substrate 101 includes a material or materials having the same or a similar composition with respect to semiconductor structures 109. In some embodiments, a portion of substrate 101 extends into a fin 114. In some embodiments, source 115 and drain 105 are epitaxial to fin 114, which may extend between source 115 and drain 105 as discussed with respect to semiconductor structures 109. For example, a single fin 114 may extend between source 115 and drain 105 in place of the stack of semiconductor structures 109 illustrated herein. In some embodiments, substrate 101 and semiconductor structures 109 include a Group IV material (e.g., silicon). In some embodiments, substrate 101 and semiconductors structures 109 include a substantially monocrystalline material. In some embodiments, substrate 101 includes a buried insulator layer (e.g., SiO₂), for example, of a semiconductor-on-insulator (SOI) substrate and or isolation insulator regions and the like. Semiconductor structures 109 may include any number of channel semiconductors, ribbons, or layers over substrate 101 such as three, four, five, or more layers. Semiconductor structures 109 are separated by layers of dummy gate 104, which will later be removed and replaced by one or more gate structures inclusive of, for example, gate dielectric materials and gate electrode materials.

For example, dummy gate 104, along with isolation materials 102, may ultimately be removed and replaced with gate dielectric material and gate electrode materials. Notably, FIG. 1 illustrates transistor structure 100, which may be further processed to form a functional device, as discussed herein below. As shown, transistor structure 100 includes source 115 and drain 105 inclusive of n-type doped epitaxial nucleation layer 107, low n-type dopant growth region 106, and high n-type dopant implant region 108. Source 115 and drain 105 are epitaxial to semiconductor structures 109 such that they are epitaxially deposited on or grown from semiconductor structures 109 and have a crystallinity epitaxial to semiconductor structures 109. For example, source 115 and drain 105 and semiconductor structures 109 may share a crystal lattice structure due to source and drain materials 105 being epitaxially grown from semiconductor structures 109.

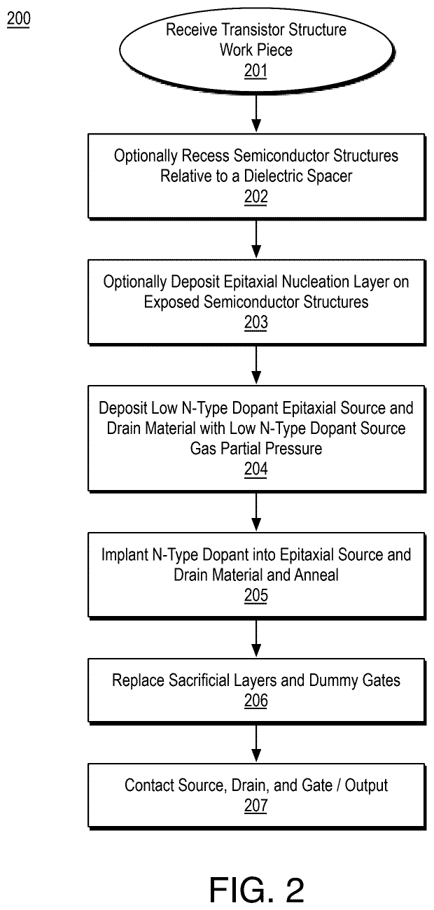

FIG. 2 illustrates a flow diagram illustrating an example process 200 for fabricating transistor structures having epitaxial source and drain structures with reduced misshapenness, arranged in accordance with at least some implementations of the present disclosure. For example, process 200 may be implemented to fabricate transistor structure 100 or any other transistor structure discussed herein. In the illustrated embodiment, process 200 includes one or more operations as illustrated by operations 201-207. However, embodiments herein may include additional operations, certain operations being omitted, or operations being performed out of the order provided.

In an embodiment, process 200 may fabricate a transistor structure having epitaxial source and drain structures that have a region or portion that has a low n-type dopant concentration and another overlying region or portion that has a high n-type dopant concentration. An entirety of the epitaxial source and drain structures are grown with epitaxial growth kinetics that reduce misshapenness of the epitaxial source and drain structures. A subsequent implant and anneal process are then performed to increase the n-type dopant concentration at the top surface for decreased contact resistance. In addition, a semiconductor recess may be performed to improve transistor device performance. For example, the process conditions for reduced misshapenness result in n-type epitaxial source and drain structures that reduce the risk of shorts and other issues due to misshapenness. However, the resultant n-type epitaxial source and drain structures have disadvantageous performance characteristics in terms of, for example, resistance, drain induced barrier lowering, capacitance-voltage characteristics, and others. These performance characteristics are improved through implant, anneal, and optional undercut etch.

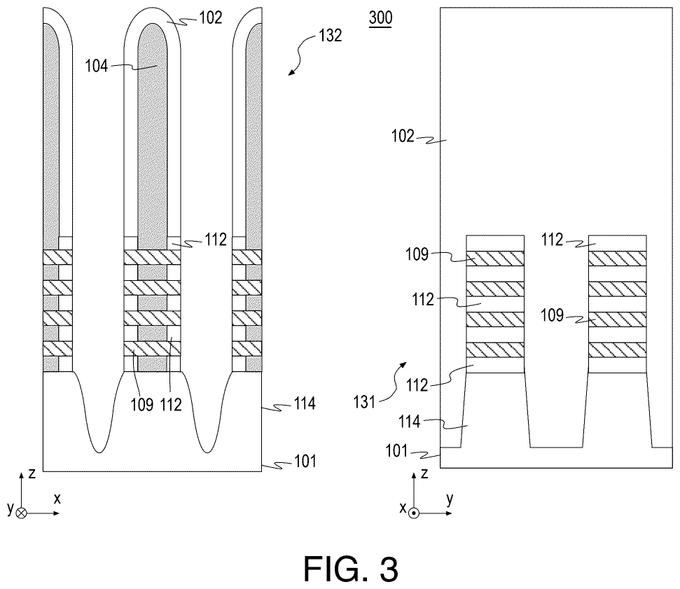

FIGS. 3, 4, 5, 6, 7, 8, 9, and 10 illustrate cross-sectional side views of example transistor structures as particular fabrication operations are performed to generate sources and drains with reduced misshapenness and improved electrical characteristics, arranged in accordance with at least some implementations of the present disclosure. Reference will be made to FIGS. 3, 4, 5, 6, 7, 8, 9, and 10 in the context of process 200.

Process 200 begins at operation 201, where a transistor structure work piece is received for processing. For example, NMOS and/or PMOS transistor structures may be formed within, on, and/or over a substrate. The substrate may include any suitable substrate such as a silicon wafer or the like. The NMOS and PMOS transistor structures may be planar, multi-gate, or gate all around transistor structures formed using techniques known in the art. In gate all around examples, a multi-layer structure including alternating layers of channel semiconductor and sacrificial material layers may be deposited and patterned. Sidewall structures and sacrificial gate structures (e.g., inclusive of sacrificial gate oxide, a sacrificial or dummy gate, and an isolation layer) may then be formed as known in the art.

Referring now to FIG. 3, an example received transistor structure 300 (e.g., a transistor structure work piece) includes substrate 101, fin 114, semiconductor structures 109, and isolation materials 102, 112. Transistor structure 300 may be fabricated using any suitable technique or techniques. As shown in both of cross-sectional views 131, 132, portions of semiconductor structures 109 are exposed for growth of epitaxial source and drain materials. Isolation materials 102, 112 may be any suitable electrically insulative material or materials such as silicon oxide, silicon nitride, silicon oxynitride, or similar material(s). Isolation material 112 may also be characterized as a dielectric spacer, spacer, or spacer material as discussed further herein below. In some embodiments, isolation materials 102, 112 are the same material. In some embodiments, isolation materials 102, 112 are different materials.

Returning to FIG. 2, processing continues at operation 202, where the semiconductor structures are optionally recessed relative to the isolation materials adjacent the semiconductor structures. The recess of the semiconductor structures may be performed using any suitable technique or techniques such as selective wet etch techniques. Notably, recessing the semiconductor structures brings eventual source and drain materials closer to the channel region of the semiconductor structures. As used herein, the term channel region indicates a portion of a semiconductor structure that is switchable by a gate to selectively switch the transistor device. Notably, the transistor device need not be in operation for a region of a semiconductor structure to be characterized as a channel region or for a semiconductor structure or material to be characterized as a channel semiconductor or channel material.

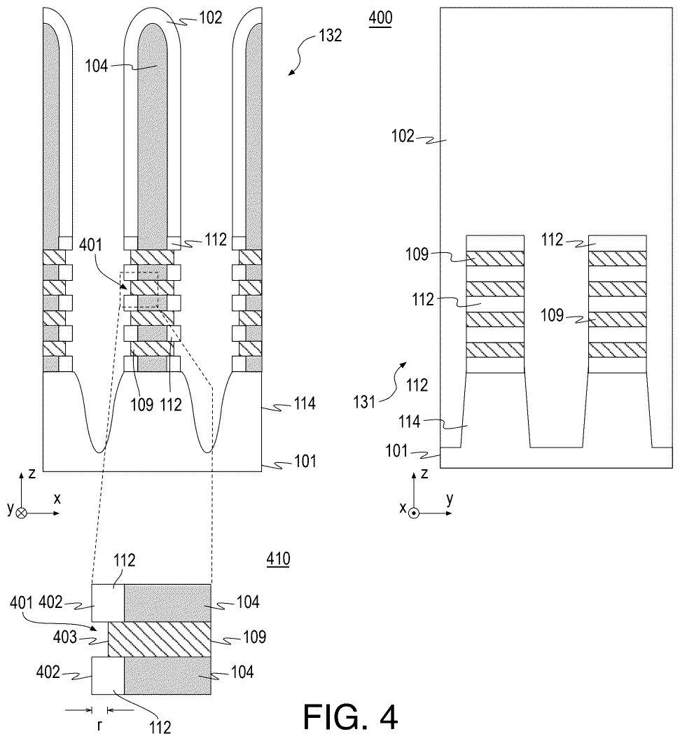

FIG. 4 illustrates an example transistor structure 400 similar to transistor structure 300 after recessing semiconductor structures 109. As discussed, semiconductor structures 109 may be recessed using any suitable technique or techniques such as selective wet etch processing. As shown, recessing semiconductor structures 109 reduces the lateral dimension (e.g., in the x-dimension) or gate length of transistor structure 400 and forms a gap 401. By reducing the gate length and the lateral length of semiconductor structures 109, the distance between the channel portion of semiconductor structures 109 and the outer walls of semiconductor structures 109 is reduced. This brings the source and drain (fabricated in subsequent operations) closer to the channel portion of semiconductor structures 109 for improved device performance.

As shown in insert 410, the recessing of semiconductor structures 109 forms an outer sidewall 402 of each semiconductor structure 109 that is recessed relative to an outer sidewall 403 of isolation material 112. As discussed, isolation material 112 may also be characterized as a dielectric spacer, spacer, or spacer material as it spaces an eventual gate structure, which will replace dummy gate 104, from eventual source 115 and drain 105. As used in this context, the term outer sidewall indicates the sidewall of the pertinent structure distal from the gate centerline of the transistor structure. The recess distance r, which is the distance between outer sidewall 402 of isolation material 112 and outer sidewall 403 of semiconductor structure 109, may be any suitable distance such as a distance in the range of 1 to 3 nm.

As discussed, gap 401 will subsequently be filled with source or drain material epitaxial to semiconductor structures 109. By forming gap 401 and reducing the lateral dimension of semiconductor structure 109, device performance is improved to mitigate the effect of growing source and drain materials with lower n-type dopant concentration for reduced misshapenness.

Returning to FIG. 2, processing continues at operation 203 and operation 204, where epitaxial source and drain materials are deposited via growth from the exposed portions of the semiconductor structures. At operation 203, an epitaxial nucleation layer may be deposited. At operation 204, low n-type dopant epitaxial source and drain materials are deposited with low n-type dopant source gas partial pressure. The epitaxial source and drain materials may be deposited using any suitable technique or techniques such as chemical vapor deposition including dopant materials. In some embodiments, operations 203, 204 are performed in the same processing chamber sequentially such that, for example, a processing work piece (e.g., wafer) is not removed from the chamber during such operations. In some embodiments, operation 203 may be bypassed and the low n-type dopant epitaxial source and drain materials may be directly deposited on the exposed semiconductor structures. In some embodiments, a lower n-type dopant concentration seed or nucleation layer is first formed for lattice matching and improved growth consistency.

The epitaxial deposition at least at operation 204 leverages growth kinetics of the chosen source gases and partial pressures to reduce the misshapenness in the resultant n-type epitaxial source and drain materials. In some embodiments, the n-type dopant gas is phosphine (PH₃) to supply the n-type dopant, phosphorus. In some embodiments, the n-type dopant gas is arsine (AsH₃) to supply the n-type dopant, arsenic. In some embodiments, the bulk material gas is one of dichlorosilane (Si₂H₂Cl₂), disilane (Si₂H₆), or silane (SiH₄) to provide the silicon semiconductor bulk material. For example, a phosphorus source gas may include phosphine and a silicon source gas may include one of dichlorosilane, disilane, or silane to form phosphorus doped silicon epitaxial source and drain materials in the epitaxial deposition process.

In some embodiments, the phosphine partial pressure is reduced relative to deposition conditions of for high n-type dopant concentration to reduce misshapenness in the resultant epitaxial material. In some embodiments, epitaxially depositing the source and drain materials includes simultaneously flowing (e.g., co-flowing) a silicon source gas and a phosphorus source gas such that the phosphorus source gas has a first partial pressure of not more than ten percent of second partial pressure of the silicon source gas. Such co-flowing provides for in-situ doping of the epitaxial material. In some embodiments, the phosphorus source gas has a first partial pressure of not more than five percent of second partial pressure of the silicon source gas. In some embodiments, the phosphorus source gas has a first partial pressure of not more than twenty percent of second partial pressure of the silicon source gas. Other partial pressures may be used. In such contexts, the phosphorus source gas may be phosphine and the silicon source gas may be any of dichlorosilane, disilane, or silane.

While not being bound by theory, by reducing the phosphine partial pressure in the phosphorus doped silicon (Si:P doped) chemical deposition process, phosphorus clustering on the surface may be suppressed. Thereby, the silicon and phosphorus adatom competition may be reduced on the growth surface resulting in a more uniform growth and therefore suppression in the misshapenness of the resultant epitaxial material. For example, during growth at higher phosphine partial pressure (and greater dopant concentration), as silicon and phosphorus atoms are being incorporated at the surface, greater amounts of phosphorus cause difficulty in silicon atoms being incorporated, which may cause small, local (e.g., nano-scale) areas having silicon growth being blocked by phosphorus. This can cause misshapenness, which can be resolved by reducing the amount of phosphorus so silicon can be grown more evenly, as discussed herein. Since the reduction in the phosphine flow also reduces the phosphorus concentration, phosphorus is implanted into the epitaxial material to recover the loss in electrical conductivity of the bulk epitaxial material to subsequent silicide source and drain contacts, as discussed herein below with respect to operation 205.

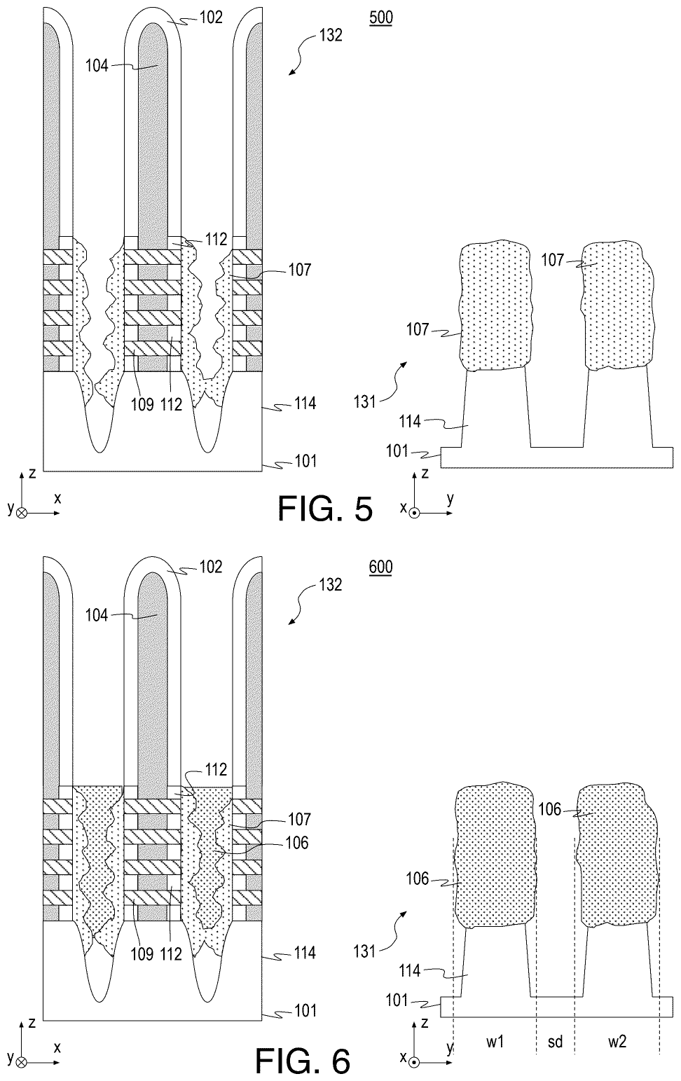

FIG. 5 illustrates an example transistor structure 500 similar to transistor structure 400 after the epitaxial growth of n-type doped epitaxial nucleation layer 107. As shown, optional n-type doped epitaxial nucleation layer 107 is grown epitaxial to semiconductor structures 109, and a n-type doped epitaxial nucleation layer 107 may have perturbations such that n-type doped epitaxial nucleation layer 107 has a relatively non-uniform outer surfaces. In some embodiments, n-type doped epitaxial nucleation layer 107 is a doped epitaxial semiconductor such as phosphorus doped silicon. In some embodiments, n-type doped epitaxial nucleation layer 107 has a lower dopant concentration than low n-type dopant growth region 106.

FIG. 6 illustrates an example transistor structure 600 similar to transistor structure 500 after the epitaxial growth of low n-type dopant growth region 106. As shown, in some embodiments, low n-type dopant growth region 106 is grown epitaxial to optional n-type doped epitaxial nucleation layer 107. In some embodiments, low n-type dopant growth region 106 is grown epitaxial to semiconductor structures 109, and optional n-type doped epitaxial nucleation layer 107 is not deployed. As discussed, low n-type dopant growth region 106 is grown with a low partial pressure of the phosphorus source gas (e.g., phosphorus precursor) relative to that of the silicon source gas (e.g., silicon precursor). For example, the partial pressure of the phosphorus source gas may be not more than five percent, not more than ten percent, or not more than twenty percent of the partial pressure of the silicon source gas. In some embodiments, the phosphorus source gas is phosphine and the silicon source gas is one or more of dichlorosilane, disilane, or silane.

By reducing misshapenness of the epitaxial structure via deployment of low n-type dopant growth region 106, greater widths w1, w2 may be targeted in transistor structure 600. Furthermore, beginning with a lower phosphorus concentration at source/drain deposition and later implant to increase dopant concentration can prevent thermally-enhanced phosphorus diffusion into the surrounding dielectric material (e.g., isolation materials 112) and into the tips of channel semiconductor 109, which can exacerbate short channel effects.

In some embodiments, the standard deviation of a statistically significant number of source or drain widths is not more than ten percent of the mean source or drain width. In some embodiments, the standard deviation of a statistically significant number of source or drain widths is not more than eight percent of the mean source or drain width. In some embodiments, the standard deviation of a statistically significant number of source or drain widths is not more than six percent of the mean source or drain width. In some embodiments, the standard deviation of a statistically significant number of source or drain widths is not more than five percent of the mean source or drain width. In some embodiments, the standard deviation of a statistically significant number of source or drain widths is not more 2 nm.

Returning to FIG. 2, processing continues at operation 205, where n-type dopants are implanted into the top surface of the epitaxial source and drain materials deposited at operations 203, 204, and a subsequent anneal is performed. The implant may be performed using any suitable technique or techniques. In some embodiments, phosphine gas is used as an ion source to provide a phosphorus implant species in an ion implantation process. The implant is deployed to bring a top region of the epitaxial source and drain materials to a higher n-type dopant concentration such as a higher phosphorus dopant concentration of silicon. Similarly, the subsequent anneal may be performed using any suitable technique or techniques. In some embodiments, the anneal process recombines the implant species into crystalline vacancies and resolves crystalline damage caused by the implant process. In some embodiments, the anneal is performed at a temperature in the range of 500 to 1300° C., however any suitable processing temperature and durations may be used.

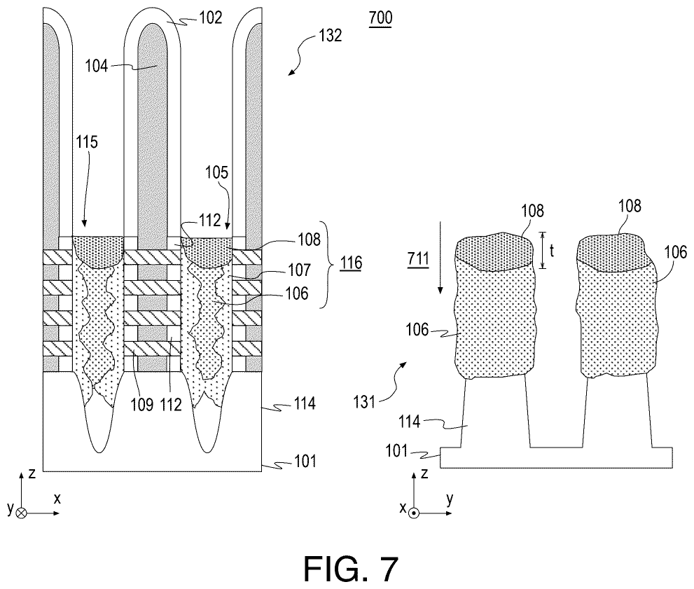

FIG. 7 illustrates an example transistor structure 700 similar to transistor structure 600 after implant and anneal processing to form high n-type dopant implant region 108 in a portion of low n-type dopant growth region 106 and, optionally, in a portion of n-type doped epitaxial nucleation layer 107. As discussed, high n-type dopant implant region 108 may be formed to recover the loss in electrical conductivity due to the low n-type dopant concentration of low n-type dopant growth region 106.

In some embodiments, the bulk low n-type dopant concentration of low n-type dopant growth region 106 is at a depth below a thickness t of high n-type dopant implant region 108. For example, the bulk low n-type dopant concentration of low n-type dopant growth region 106 may be below a thickness t of between 5 to 10 nm below the top surface of source 115 or drain 105. In some embodiments, high n-type dopant implant region 108 has a reducing gradient of dopant concentration along an implant direction 711 (i.e., the negative z-direction). Notably, high n-type dopant implant region 108 may have the dopant concentrations discussed herein at some or all sub-regions of high n-type dopant implant region 108.

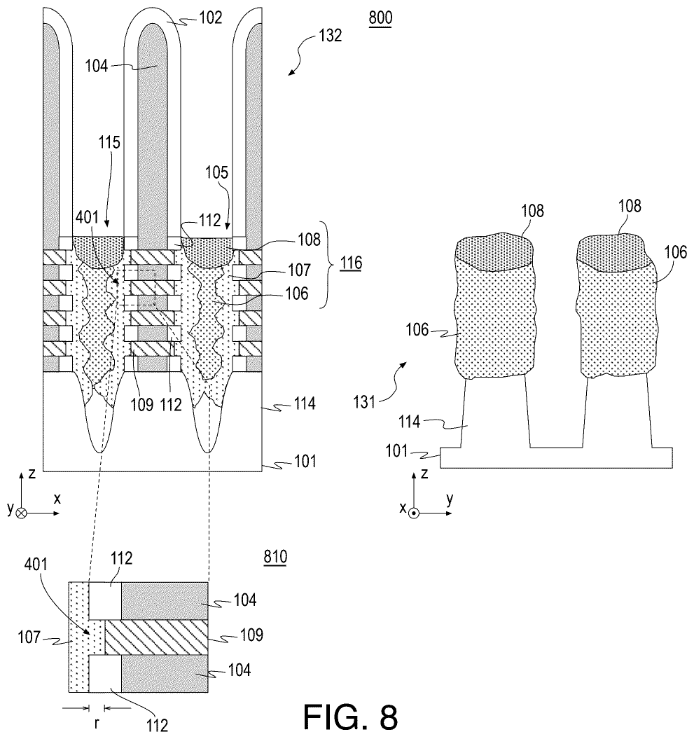

FIG. 8 illustrates an example transistor structure 800 similar to transistor structure 700 with semiconductor structures 109 being recessed. For example, processing may continue from FIG. 4 as discussed with respect to FIGS. 5, 6, 7. Transistor structure 800 may have any characteristics discussed herein and, as shown, includes gap 401 being filled with n-type doped epitaxial nucleation layer 107 or low n-type dopant growth region 106.

As discussed, recessing semiconductor structures 109 reduces the lateral dimension (e.g., in the x-dimension) or gate length of transistor structure 800, which brings source 115 and drain 105 and, specifically, n-type doped epitaxial nucleation layer 107 or low n-type dopant growth region 106 closer to the channel portion of semiconductor structures 109, as illustrated in insert 810. This improves device performance and compensates for the relatively low concentration of n-type dopant in n-type doped epitaxial nucleation layer 107 and/or low n-type dopant growth region 106.

Returning to FIG. 2, after such low misshapenness source/drain epitaxial fabrication, processing continues at operation 206, where the sacrificial layers adjacent the channel semiconductor the dummy gate materials may be replaced with gate structures using any suitable technique or techniques known in the art. For example, the sacrificial layers may be selectively etched and the requisite structures may be formed via deposition and optional patterning techniques. Processing continues at operation 207, where the source and drain semiconductor and gate structures are contacted via metal contacts using any suitable technique or techniques such as patterning and metal deposition processing as is known in the art.

Furthermore, at operation 207, additional fabrication may be completed and the resultant structure may be output. Such processing may include any additional backend processing, dicing, packaging, assembly, and so on. The resultant device (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

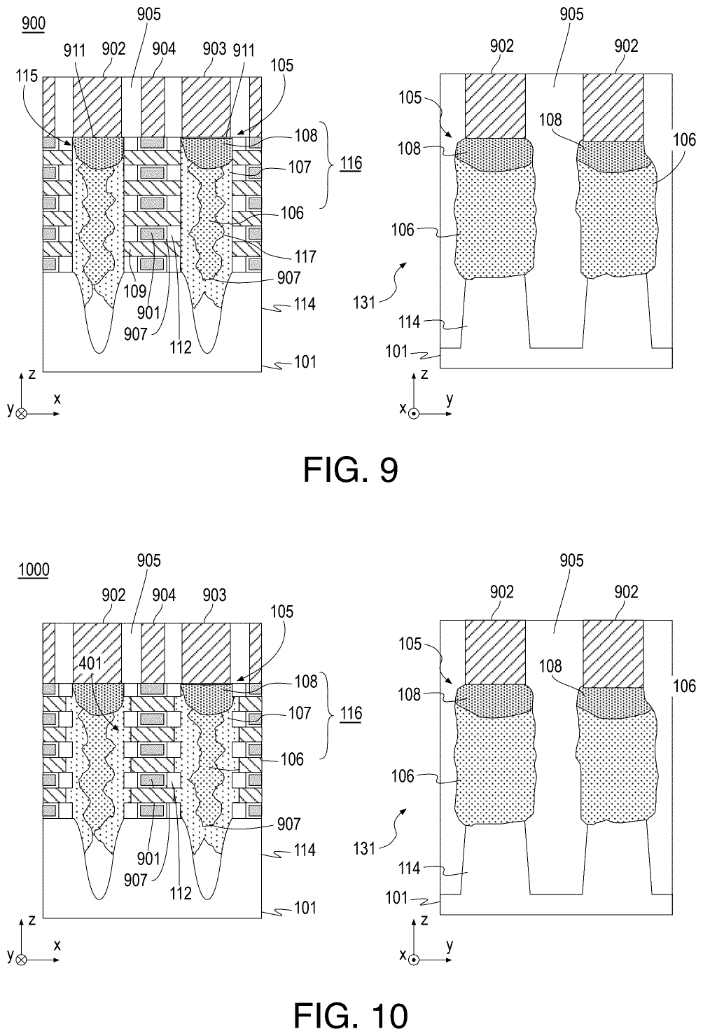

FIG. 9 illustrates an example transistor structure 900 similar to transistor structure 700 after the formation of gate structures and source, drain, and gate contacts, arranged in accordance with at least some implementations of the present disclosure. As shown, isolation material 102 and dummy gate 104 are removed and are, at least in part, replaced by gate dielectric 907, gate electrode 901, source contact 902, drain contact 903, gate contact 904, and isolation material 905. Such processing may be performed using operations known in the art. Furthermore, such components may include any suitable materials. for example, gate dielectric 907 may be a high-k material such as hafnium oxide, gate electrode 901 may include a work function material such as a metal, and source contact 902, drain contact 903, gate contact 904 may include contact metals.

In some embodiments, a silicide material is formed at an interface 911 between high n-type dopant implant region 108 and source contact 902 and drain contact 903. For example, a silicide inclusive of a combination of silicon and a metal may be formed, and a bulk source contact 902 and drain contact 903 may then be formed on the silicide. As used herein, the terms source contact 902 and drain contact 903 are inclusive of any silicide, and interface 911 is therefore between source contact 902 and drain contact 903 and high n-type dopant implant region 108.

Notably, transistor structure 900 includes one or more semiconductor structures 109 (e.g., channel semiconductors) over substrate 101 and extending between source 115 and drain 105, which are epitaxial to the one or more semiconductor structures 109. Source 115 and drain 105 include epitaxial structures (e.g., at least low n-type dopant growth region 106 and high n-type dopant implant region 108) having a first material and an n-type dopant. In some embodiments, the first material is silicon, and the n-type dopant is phosphorus. In some embodiments, the n-type dopant is arsenic. In some embodiments, source 115 and drain 105 are not less than 99% of the first material and the n-type dopant and exclusive of other materials.

Transistor structure 900 further includes a gate structure (e.g., gate electrode 901 and gate dielectric 907) coupled to the one or more semiconductor structures 109, and source contact 902 and drain contact 903 on the epitaxial structures (e.g., on high n-type dopant implant region 108). In some embodiments, the epitaxial structures include a first region (e.g., low n-type dopant growth region 106) lateral to the semiconductor structure and a second region (e.g., high n-type dopant implant region 108) over the first region. High n-type dopant implant region 108 is adjacent to interface 911 (e.g., source contact and drain contact are on each high n-type dopant implant region 108), and absent any sidewall 117 of low n-type dopant growth region 106. As discussed, low n-type dopant growth region 106 has a first n-type dopant concentration less than a second n-type dopant concentration of high n-type dopant implant region 108. In some embodiments, low n-type dopant growth region 106 has a first n-type dopant concentration of not more than 70 percent of a second n-type dopant concentration of high n-type dopant implant region 108.

As shown, high n-type dopant implant region 108 extends across an entirety of a width of the epitaxial structure with high n-type dopant implant region 108 at interfaces 911 with source contact 902 and drain contact 903 and at an interface with low n-type dopant growth region 106. As discussed, low n-type dopant growth region 106 may be not less than 5 nm from interfaces 911 in the z-dimension. Also, as shown, high n-type dopant implant region 108 extends below the interface with low n-type dopant growth region 106.

FIG. 10 illustrates an example transistor structure 1000 similar to transistor structure 900 with semiconductor structures 109 being recessed. For example, processing may continue from FIG. 8 as discussed with respect to FIG. 9. Transistor structure 1000 has any characteristics discussed herein and, as shown, includes gap 401 filled with n-type doped epitaxial nucleation layer 107 or low n-type dopant growth region 106 (refer to FIG. 8).

By recessing semiconductor structures 109, the lateral dimension (e.g., in the x-dimension) or gate length of transistor structure 1000 is reduced to bring source 115 and drain 105 closer to the channel portion of semiconductor structures 109. For example, n-type doped epitaxial nucleation layer 107 or low n-type dopant growth region 106 are closer to the channel portion as compared to no recess processing, which can improve device performance to compensate for the relatively low concentration of n-type dopant in n-type doped epitaxial nucleation layer 107 and/or low n-type dopant growth region 106 at the expense of greater process complexity.

The n-type dopant concentrations discussed herein above may be determined using any suitable technique or techniques. In some embodiments, atom probe tomography (APT) or time-of-flight secondary ion mass spectroscopy (TOFSIMS) may detect a gradient in the phosphorus concentration, more specifically a highly doped region 5-10 nm close to the silicide interface followed by a lower concentration (up to 30-70% less than the maximum concentration) of phosphorus in the bulk of the Epi (>5-10 nm away from the silicide interface). Herein, a region may be any portion of the pertinent component having the discussed characteristics. Notably, the discussed dopant concentrations and other characteristics may not be same across all sample instances of a particular material or component. Furthermore, the discussed n-type epi size uniformity (e.g., low standard deviation in variance from the mean) may be measured via either planar scanning electron microscope (SEM) or low-resolution transmission electron microscope (TEM) or a wide-field of view X-TEM capturing a statistically significant number of n-epis.

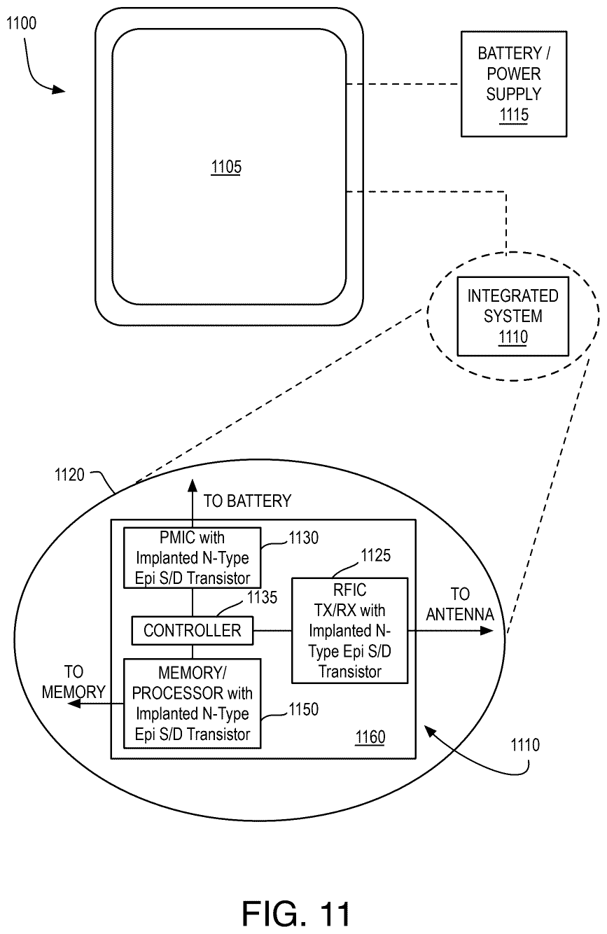

FIG. 11 is an illustrative diagram of a mobile computing platform 1100 employing a device having a reduced misshapenness implanted epitaxial (Epi) source and/or drain (S/D) transistor, arranged in accordance with at least some implementations of the present disclosure. Any die or device having a transistor structure inclusive of any components, materials, or characteristics discussed herein may be implemented by any component of mobile computing platform 1100. Mobile computing platform 1100 may be any portable device configured for each of electronic data display, electronic data processing, wireless electronic data transmission, or the like. For example, mobile computing platform 1100 may be any of a tablet, a smart phone, a netbook, a laptop computer, etc. and may include a display screen 1105, which in the exemplary embodiment is a touchscreen (e.g., capacitive, inductive, resistive, etc. touchscreen), a chip-level (system on chip-SoC) or package-level integrated system 1110, and a battery/power supply 1115. Battery/power supply may include any suitable device for providing electrical power such as a device including one or more electrochemical cells and electrodes to couple to an outside device. Battery/power supply 1115 may be incorporated in mobile computing platform 1100, and may further include a power supply or other circuitry to convert a source power from a source voltage to one or more voltages employed by other devices of mobile computing platform 1100. For example, battery/power supply 1115 may be coupled to an IC die including transistor structures having any components, materials, or characteristics discussed herein.

Integrated system 1110 is further illustrated in the expanded view 1120. In the exemplary embodiment, packaged device 1150 (labeled “Memory/Processor” in FIG. 11) includes at least one memory chip (e.g., RAM), and/or at least one processor chip (e.g., a microprocessor, a multi-core microprocessor, or graphics processor, or the like). In an embodiment, the package device 1150 is a microprocessor including an SRAM cache memory. As shown, device 1150 may employ a die or device having any transistor structures and/or related characteristics discussed herein. Packaged device 1150 may be further coupled to (e.g., communicatively coupled to) a board, a substrate, or an interposer 1160 along with, one or more of a power management integrated circuit (PMIC) 1130, RF (wireless) integrated circuit (RFIC) 1125 including a wideband RF (wireless) transmitter and/or receiver (TX/RX) (e.g., including a digital baseband and an analog front end module further comprises a power amplifier on a transmit path and a low noise amplifier on a receive path), and a controller 1135 thereof. In general, packaged device 1150 may also be coupled to (e.g., communicatively coupled to) display screen 1105. As shown, one or both of PMIC 1130 and/or RFIC 1125 may employ a die or device having any transistor structures and/or related characteristics discussed herein.

Functionally, PMIC 1130 may perform battery power regulation, DC-to-DC conversion, etc., and so has an input coupled to battery 1115 and with an output providing a current supply to other functional modules. In an embodiment, PMIC 1130 may perform high voltage operations. As further illustrated, in the exemplary embodiment, RFIC 1125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. In alternative implementations, each of these board-level modules may be integrated onto separate ICs coupled to the package substrate of packaged device 1150 or within a single IC (SoC) coupled to the package substrate of the packaged device 1150.

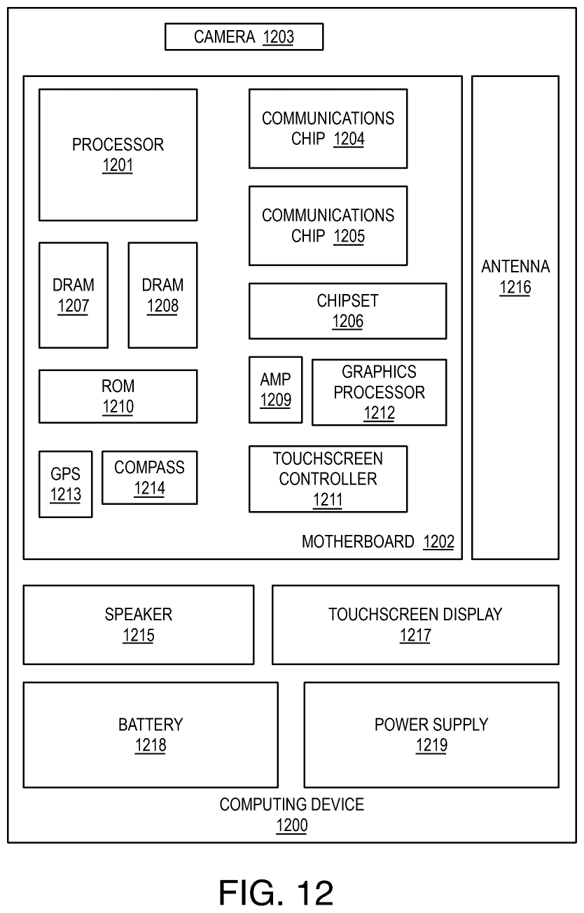

FIG. 12 is a functional block diagram of a computing device 1200, arranged in accordance with at least some implementations of the present disclosure. Computing device 1200 may be found inside platform 1100, for example, and further includes a motherboard 1202 hosting a number of components, such as but not limited to a processor 1201 (e.g., an applications processor) and one or more communications chips 1204, 1205. Processor 1201 may be physically and/or electrically coupled to motherboard 1202. In some examples, processor 1201 includes an integrated circuit die packaged within the processor 1201. In general, the term “processor” may refer to any device or portion of a device that processes electronic data from registers and/or memory to transform that electronic data into other electronic data that may be stored in registers and/or memory. Any one or more device or component of computing device 1200 may include a die or device having any transistor structures and/or related characteristics discussed herein as discussed herein.

In various examples, one or more communication chips 1204, 1205 may also be physically and/or electrically coupled to the motherboard 1202. In further implementations, communication chips 1204 may be part of processor 1201. Depending on its applications, computing device 1200 may include other components that may or may not be physically and electrically coupled to motherboard 1202. These other components may include, but are not limited to, volatile memory (e.g., DRAM) 1207, 1208, non-volatile memory (e.g., ROM) 1210, a graphics processor 1212, flash memory, global positioning system (GPS) device 1213, compass 1214, a chipset 1206, an antenna 1216, a power amplifier 1209, a touchscreen controller 1211, a touchscreen display 1217, a speaker 1215, a camera 1203, a battery 1218, and a power supply 1219, as illustrated, and other components such as a digital signal processor, a crypto processor, an audio codec, a video codec, an accelerometer, a gyroscope, and a mass storage device (such as hard disk drive, solid state drive (SSD), compact disk (CD), digital versatile disk (DVD), and so forth), or the like.

Communication chips 1204, 1205 may enable wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1204, 1205 may implement any of a number of wireless standards or protocols, including but not limited to those described elsewhere herein. As discussed, computing device 1200 may include a plurality of communication chips 1204, 1205. For example, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. Furthermore, power supply 1219 may convert a source power from a source voltage to one or more voltages employed by other devices of mobile computing platform 1200. In some embodiments, power supply 1219 converts an AC power to DC power. In some embodiments, power supply 1219 converts an DC power to DC power at one or more different (lower) voltages. In some embodiments, multiple power supplies are staged to convert from AC to DC and then from DC at a higher voltage to DC at a lower voltage as specified by components of computing device 1200.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In one or more first embodiments, an apparatus, such as a transistor structure, comprises a semiconductor structure extending between a source and a drain, such that the source and the drain are epitaxial to the semiconductor structure, and such that at least one of the source or the drain comprises an epitaxial structure comprising a first material doped with an n-type dopant, a gate structure coupled to the semiconductor structure, and a source or drain contact on the epitaxial structure at an interface therebetween, such that the epitaxial structure comprises a first region lateral to the semiconductor structure and a second region over the first region, adjacent to the interface, and absent a sidewall of the first region, such that the first region has a first n-type dopant concentration of not more than 70 percent of a second n-type dopant concentration of the second region.

In one or more second embodiments, further to the first embodiments, the first region extends across an entirety of a width of the epitaxial structure, the second region is at a second interface between the second region and the first region, the first region is not less than 5 nm from the interface, and no portion of the second region extends below the second interface.

In one or more third embodiments, further to the first or second embodiments, the first material is silicon, the n-type dopant is phosphorus, and the first n-type dopant concentration is not more than 2.5×10²¹ cm⁻³.

In one or more fourth embodiments, further to the first through third embodiments, the semiconductor structure comprises one of a plurality of stacked semiconductor structures, the plurality of stacked semiconductor structures comprising a top semiconductor structure, such that the second region is lateral to the top semiconductor structure.

In one or more fifth embodiments, further to the first through fourth embodiments, the apparatus further comprises a dielectric spacer between the gate structure and the second region, such that the top semiconductor structure has an outer sidewall that is recessed relative to an outer sidewall of the dielectric spacer.

In one or more sixth embodiments, further to the first through fifth embodiments, the apparatus further comprises a plurality of second stacked semiconductor structures extending between the source or the drain comprising the epitaxial structure, and a second source or a second drain, such that the second region comprises an entirety of a top surface of the source or the drain between the stacked semiconductor structures and the second stacked semiconductor structures.

In one or more seventh embodiments, further to the first through sixth embodiments, the apparatus further comprises a doped epitaxial nucleation layer between the first region and the semiconductor structure.

In one or more eighth embodiments, further to the first through seventh embodiments, the apparatus further comprises a power supply, and an integrated circuit die coupled to the power supply, the integrated circuit die comprising the semiconductor structure, the source, the drain, the gate structure, and the source or drain contact.

In one or more ninth embodiments, a system comprises an integrated circuit die having an apparatus according to any of the apparatuses of the first through seventh embodiments, the system further comprising a power supply or a display coupled to the integrated circuit die.

In one or more tenth embodiments, an apparatus, such as a transistor structure, comprises a semiconductor structure extending between a source and a drain, such that at least one of the source or the drain comprises an epitaxial structure comprising silicon doped with phosphorus, a gate structure coupled to the semiconductor structure, and a source or drain contact on the epitaxial structure, such that the epitaxial structure comprises a first region lateral to the semiconductor structure and an implant region extending between the first region and the source or drain contact.

In one or more eleventh embodiments, further to the tenth embodiments, the first region has a phosphorus concentration of not more than 2.5×10²¹ cm⁻³ and the implant region has a phosphorus concentration of not less than 3.0×10²¹ cm⁻³.

In one or more twelfth embodiments, further to the tenth or eleventh embodiments, the first region has a first phosphorus concentration of not more than 70 percent of a second phosphorus concentration of the implant region.

In one or more thirteenth embodiments, further to the tenth through twelfth embodiments, the apparatus further comprises a second semiconductor structure extending between the source or the drain comprising the epitaxial structure and a second source or a second drain, such that the implant region comprises an entirety of a top surface of the source or the drain between the semiconductor structure and the second semiconductor structure.

In one or more fourteenth embodiments, further to the tenth through thirteenth embodiments, the semiconductor structure comprises one of a plurality of stacked semiconductor structures, the plurality of stacked semiconductor structures comprising a top semiconductor structure, such that the implant region is lateral to the top semiconductor structure.

In one or more fifteenth embodiments, further to the tenth through fourteenth embodiments, the apparatus further comprises a dielectric spacer between the gate structure and the implant region, such that the top semiconductor structure has an outer sidewall that is recessed relative to an outer sidewall of the dielectric spacer.

In one or more sixteenth embodiments, further to the tenth through fifteenth embodiments, the apparatus further comprises a power supply, and an integrated circuit die coupled to the power supply, the integrated circuit die comprising the semiconductor structure, the source, the drain, the gate structure, and the source or drain contact.

In one or more seventeenth embodiments, a system comprises an integrated circuit die having an apparatus according to any of the apparatuses of the tenth through fifteenth embodiments, the system further comprising a power supply or a display coupled to the integrated circuit die.

In one or more eighteenth embodiments, a method comprises receiving a transistor structure comprising a channel semiconductor over a substrate, epitaxially depositing source and drain materials on the channel semiconductor, the source and drain materials having a first concentration of an n-type dopant species of not more than 2.5×10²¹ cm⁻³, implanting the n-type dopant species into the source and drain materials, and annealing the source and drain materials to form top regions of the source and drain materials, the top regions having a second concentration of the n-type dopant species of not less than 3.0×10²¹ cm⁻³.

In one or more nineteenth embodiments, further to the eighteenth embodiments, epitaxially depositing the source and drain materials comprises simultaneously flowing a silicon source gas and a phosphorus source gas, such that the phosphorus source gas has a first partial pressure of not more than ten percent of second partial pressure of the silicon source gas.

In one or more twentieth embodiments, further to the eighteenth or nineteenth embodiments, the phosphorus source gas comprises phosphine (PH₃) and the silicon source gas comprises one of dichlorosilane, disilane, or silane.

In one or more twenty-first embodiments, further to the eighteenth through twentieth embodiments, the method further comprises recessing, prior to said epitaxially depositing the source and drain materials, the channel semiconductor relative to an adjacent dielectric spacer.

In one or more twenty-second embodiments, further to the eighteenth through twenty-first embodiments, epitaxially depositing the source and drain materials comprises depositing a doped epitaxial nucleation layer on the channel semiconductor and depositing a fill layer, the fill layer having the first concentration and the doped epitaxial nucleation layer having a second concentration of the n-type dopant species less than the first concentration.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a semiconductor structure extending between a source and a drain, wherein the source and the drain are epitaxial to the semiconductor structure, and wherein at least one of the source or the drain comprises an epitaxial structure comprising a first material doped with an n-type dopant;
a gate structure coupled to the semiconductor structure; and
a source or drain contact on the epitaxial structure at an interface therebetween, wherein the epitaxial structure comprises a first region lateral to the semiconductor structure and a second region over the first region, adjacent to the interface, and absent a sidewall of the first region, wherein the first region has a first n-type dopant concentration of not more than 70 percent of a second n-type dopant concentration of the second region.

2. The apparatus of claim 1, wherein the first region extends across an entirety of a width of the epitaxial structure, the second region is at a second interface between the second region and the first region, the first region is not less than 5 nm from the interface, and no portion of the second region extends below the second interface.

3. The apparatus of claim 1, wherein the first material is silicon, the n-type dopant is phosphorus, and the first n-type dopant concentration is not more than 2.5×10²¹ cm⁻³.

4. The apparatus of claim 1, wherein the semiconductor structure comprises one of a plurality of stacked semiconductor structures, the plurality of stacked semiconductor structures comprising a top semiconductor structure, wherein the second region is lateral to the top semiconductor structure.

5. The apparatus of claim 4, further comprising a dielectric spacer between the gate structure and the second region, wherein the top semiconductor structure has an outer sidewall that is recessed relative to an outer sidewall of the dielectric spacer.

6. The apparatus of claim 4, further comprising:
a plurality of second stacked semiconductor structures extending between the source or the drain comprising the epitaxial structure, and a second source or a second drain, wherein the second region comprises an entirety of a top surface of the source or the drain between the stacked semiconductor structures and the second stacked semiconductor structures.

7. The apparatus of claim 1, further comprising a doped epitaxial nucleation layer between the first region and the semiconductor structure.

8. The apparatus of claim 1, further comprising:
a power supply; and
an integrated circuit die coupled to the power supply, the integrated circuit die comprising the semiconductor structure, the source, the drain, the gate structure, and the source or drain contact.

9. An apparatus, comprising:
a semiconductor structure extending between a source and a drain, wherein at least one of the source or the drain comprises an epitaxial structure comprising silicon doped with phosphorus;
a gate structure coupled to the semiconductor structure; and
a source or drain contact on the epitaxial structure, wherein the epitaxial structure comprises a first region lateral to the semiconductor structure and an implant region extending between the first region and the source or drain contact.

10. The apparatus of claim 9, wherein the first region has a phosphorus concentration of not more than 2.5×10²¹ cm⁻³ and the implant region has a phosphorus concentration of not less than 3.0×10²¹ cm⁻³.

11. The apparatus of claim 9, wherein the first region has a first phosphorus concentration of not more than 70 percent of a second phosphorus concentration of the implant region.

12. The apparatus of claim 9, further comprising:
a second semiconductor structure extending between the source or the drain comprising the epitaxial structure and a second source or a second drain, wherein the implant region comprises an entirety of a top surface of the source or the drain between the semiconductor structure and the second semiconductor structure.

13. The apparatus of claim 9, wherein the semiconductor structure comprises one of a plurality of stacked semiconductor structures, the plurality of stacked semiconductor structures comprising a top semiconductor structure, wherein the implant region is lateral to the top semiconductor structure.

14. The apparatus of claim 13, further comprising a dielectric spacer between the gate structure and the implant region, wherein the top semiconductor structure has an outer sidewall that is recessed relative to an outer sidewall of the dielectric spacer.

15. The apparatus of claim 9, further comprising:
a power supply; and
an integrated circuit die coupled to the power supply, the integrated circuit die comprising the semiconductor structure, the source, the drain, the gate structure, and the source or drain contact.

16. A method, comprising:
receiving a transistor structure comprising a channel semiconductor over a substrate;
epitaxially depositing source and drain materials on the channel semiconductor, the source and drain materials having a first concentration of an n-type dopant species of not more than 2.5×10²¹ cm⁻³;
implanting the n-type dopant species into the source and drain materials; and
annealing the source and drain materials to form top regions of the source and drain materials, the top regions having a second concentration of the n-type dopant species of not less than 3.0×10²¹ cm⁻³.

17. The method of claim 16, wherein epitaxially depositing the source and drain materials comprises simultaneously flowing a silicon source gas and a phosphorus source gas, wherein the phosphorus source gas has a first partial pressure of not more than ten percent of second partial pressure of the silicon source gas.

18. The method of claim 17, wherein the phosphorus source gas comprises phosphine (PH₃) and the silicon source gas comprises one of dichlorosilane, disilane, or silane.

19. The method of claim 16, further comprising:
recessing, prior to said epitaxially depositing the source and drain materials, the channel semiconductor relative to an adjacent dielectric spacer.

20. The method of claim 16, wherein epitaxially depositing the source and drain materials comprises depositing a doped epitaxial nucleation layer on the channel semiconductor and depositing a fill layer, the fill layer having the first concentration and the doped epitaxial nucleation layer having a second concentration of the n-type dopant species less than the first concentration.
